(19) United States
(12) Patent Application Publication
(10) Pub. No.: US 2018/0166888 A1
(43) Pub. Date: Jun. 14, 2018

(54) Managing Battery Charge Status To Provide Safe Operation For Electronic Devices

(71) Applicant: BAE Systems Controls Inc., Endicott, NY (US)

(72) Inventor: Robert A. Hess, Newark Valley, NY (US)

(73) Assignee: BAE Systems Controls Inc., Endicott, NY (US)

(21) Appl. No.: 15/377,114

(22) Filed: Dec. 13, 2016

(51) Int. Cl. H02J 7/00; G01R 31/36; G01R 19/165

(52) U.S. Cl. CPC H02J 7/007; G01R 19/165; G01R 31/3606; H02J 7/0029

(57) ABSTRACT

Intelligent safety management for a battery is performed by applying a charging voltage to the battery, monitoring an actual charge level of the battery, determining a first charging voltage and a first charge level for the battery for charging the battery, and determining a second charging voltage and a second charge level for the battery that substantially reduces or eliminates a safety hazard associated with the battery. The second charging voltage is less than the first charging voltage and the second charge level is less than the first charge level. The applied charging voltage is limited so that the actual charge level of the battery does not exceed the second charge level.

### STATEMENT OF GOVERNMENT INTEREST

Not applicable.

### BACKGROUND

### 1. Field

The present disclosure relates generally to battery charging and, more particularly, to methods and apparatuses for managing battery charge status to provide safe operation for electronic devices.

### 2. Brief Description

There is an increased interest in using battery-powered electronic devices in vehicles and other enclosed spaces. A few illustrative examples of these devices include tablets, smartphones, vehicular navigation systems, and global positioning system (GPS) devices. The electronic devices may be portable, or embedded into an existing system, or both. An electronic device that is embedded into an existing system is generally connected to an external power source to support charging of the battery in the device. Such batteries provide a modest capacity, such as 20 Watt-hours (Wh) to 100 Wh. This capacity is much greater than what is needed for many embedded electronic devices, where the battery is continually connected to a power source provided by the embedded system. Of course, it may be desirable to maintain some level of energy storage in the battery if the power source of the embedded system fails or experiences a temporary outage. However, in the event of a failure or temporary outage, minutes of energy storage may suffice, and hours of energy storage may be unnecessary.

Failure of moderate capacity battery systems can result in thermal incidents, exposure to high temperatures, fire, combustion, and release of hazardous chemicals. This problem is further exacerbated when the electronic device is embedded in a hard to reach area, such as in a cabinet, in a seat, in a wall, or in a bulkhead, and cannot be quickly removed. Likewise, presently evolving regulatory requirements define distinct rules for the level of protection required in electronic devices as a function of battery capacity. Greater battery capacity implies a greater level of regulatory scrutiny. These regulatory requirements require increased levels of testing and documentation, and may also mandate hardware changes. It is possible to meet these requirements more readily by removing the battery from the electronic device. However, removing the battery from the electronic device, and performing the associated rework, increases the total cost of the electronic device, rendering the device commercially unattractive.

Use of batteries in an enclosed space presents both safety issues and potential reputational damage to a device operator. Recent events have involved battery incidents associated with e-cigarettes, battery incidents associated with high-capacity batteries of drones and hover-boards brought aboard aircraft, and aircraft fires due to battery incidents caused by improperly packaged batteries in tablet devices. Thus, there exists a need to overcome at least one of the preceding deficiencies and limitations of the related art.

### SUMMARY

A computer-implemented method for performing intelligent safety management for a battery, in one aspect, comprises applying a charging voltage to the battery, monitoring an actual charge level of the battery, determining a first charging voltage and a first charge level for the battery for charging the battery, determining a second charging voltage and a second charge level for the battery that substantially reduces or eliminates a safety hazard associated with the battery, wherein the second charging voltage is less than the first charging voltage and the second charge level is less than the first charge level, and limiting the applied charging voltage so that the actual charge level of the battery does not exceed the second charge level.

An apparatus for performing intelligent safety management for a battery in another aspect, may comprise a processor and a memory operatively coupled to the processor, wherein the memory comprises instructions which, when executed by the processor, cause the processor to apply a charging voltage from a power supply to the battery, monitor an actual charge level of the battery, determine a first charging voltage and a first charge level for the battery for charging the battery, determine a second charging voltage and a second charge level for the battery that substantially reduces or eliminates a safety hazard associated with the battery, wherein the second charging voltage is less than the first charging voltage and the second charge level is less than the first charge level, and limit the applied charging voltage so that the actual charge level of the battery does not exceed the second charge level.

A computer program product for performing intelligent safety management for a battery, in another aspect, comprises a computer-readable storage medium having a computer-readable program stored therein, wherein the computer-readable program, when executed on a computing device including at least one processor, causes the at least one processor to apply a charging voltage to the battery, monitor an actual charge level of the battery, determine a first charging voltage and a first charge level for the battery for charging the battery, determine a second charging voltage and a second charge level for the battery that substantially reduces or eliminates a safety hazard associated with the battery, wherein the second charging voltage is less than the first charging voltage and the second charge level is less than the first charge level, and limit the applied charging voltage so that the actual charge level of the battery does not exceed the second charge level.

A computer-implemented method for performing intelligent safety management for a battery, in another aspect, comprises applying a charging current to the battery, monitoring an actual charge level of the battery, determining a first charging current and a first charge level for the battery for charging the battery, determining a second charging current and a second charge level for the battery that substantially reduces or eliminates a safety hazard associated with the battery, wherein the second charging current is less than the first charging current and the second charge level is less than the first charge level, and limiting the applied charging current so that the actual charge level of the battery does not exceed the second charge level.

An apparatus for performing intelligent safety management for a battery in another aspect, may comprise a processor and a memory operatively coupled to the processor, wherein the memory comprises instructions which, when executed by the processor, cause the processor to apply a charging current from a power supply to the battery, monitor an actual charge level of the battery, determine a first charging current and a first charge level for the battery for charging the battery, determine a second charging current and a second charge level for the battery that substantially reduces or eliminates a safety hazard associated with the battery, wherein the second charging current is less than the first charging current and the second charge level is less than the first charge level, and limit the applied charging current so that the actual charge level of the battery does not exceed the second charge level.

A computer program product for performing intelligent safety management for a battery, in another aspect, comprises a computer-readable storage medium having a computer-readable program stored therein, wherein the computer-readable program, when executed on a computing device including at least one processor, causes the at least one processor to apply a charging current from a power supply to the battery, monitor an actual charge level of the battery, determine a first charging current and a first charge level for the battery for charging the battery, determine a second charging current and a second charge level for the battery that substantially reduces or eliminates a safety hazard associated with the battery, wherein the second charging current is less than the first charging current and the second charge level is less than the first charge level, and limit the applied charging current so that the actual charge level of the battery does not exceed the second charge level.

### BRIEF DESCRIPTION OF THE DRAWINGS

The invention is further described with respect to the accompanying drawings wherein:

FIG. 1 illustrates an exemplary method for performing intelligent safety management for a battery in accordance with one or more embodiments of the present invention.

FIG. 2 illustrates an exemplary apparatus on which the method of FIG. 1 may be performed in accordance with one or more embodiments of the present invention.

FIG. 3 illustrates a schematic of an exemplary computer or processing system that may implement the method of FIG. 1 according to one set of embodiments of the present invention.

### DETAILED DESCRIPTION OF THE PREFERRED EMBODIMENTS

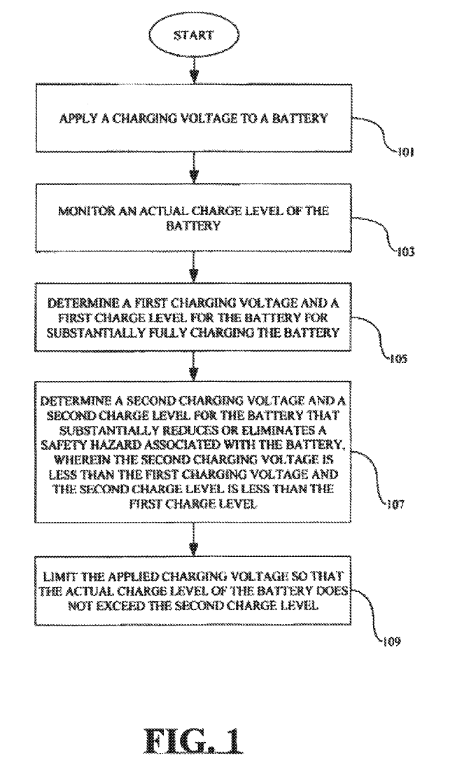

FIG. 1 illustrates an exemplary method for performing intelligent safety management for a battery in accordance with one or more embodiments of the present invention. This method may be performed at a battery-powered device or, alternatively or additionally, externally with respect to the battery-powered device. As described in greater detail hereinafter, a charge level of the battery is controlled or limited, or both, to remove or diminish the possibility of a battery thermal event, thus providing safe operation of an electronic device powered by the battery.

The operational sequence of FIG. 1 commences at block 101 where a charging voltage is applied to the battery. Alternatively or additionally, a charging current may be applied to the battery. An electronic device that is embedded into an existing system is generally connected to an external power source to support charging of the battery in the device. For purposes of illustration, such batteries provide a modest capacity, such as 20 Watt-hours (Wh) to 100 Wh.

Constant voltage chargers represent a current-limited, constant voltage source connected across the battery terminals. As the battery is charged, the voltage across the battery will increase, and the charge current will taper off. While constant voltage charging is a relatively cost-efficient approach, this technique may require long battery charge times. Since the source voltage is kept constant, as the battery is charged, the charge current, and thus the rate of charge, is rapidly reduced. The battery is then charged at a lower current rate which is generally less than the full current rate that the battery is equipped to handle.

In contrast to constant voltage charging, constant current charging applies a constant current equivalent to the battery. Even though the battery voltage reaches a termination voltage as the battery is charged, the actual battery voltage will be lower because of the voltage drop across the equivalent series resistance (ESR) of the battery. Hence, the battery may be charged to less than 100% of its capacity depending on battery ESR and charge current.

The battery is any device that generates electrical potential through a chemical reaction. In particular, the battery comprises a rechargeable battery that may be restored to operation through a charging operation. Batteries may include, but are not limited to, Nickel Cadmium (NiCad), Lithium Ion (Li-ion), Nickel Metal Anhydride (NiMH), and other rechargeable batteries. The battery may be implemented using a battery pack. The battery pack comprises a package of one or more battery cells. Battery packs are commonly used in many portable electronic devices, including mobile computing devices.

The operational sequence progresses to block 103 where an actual charge level of the battery is monitored. The charge level may be determined as a percentage of full charge, or as a percentage of full battery capacity. The charge level may be referred to as a State of Charge (SoC). For example, a battery with 100 Watt-hours (Wh) at full capacity may be presently charged to a level of 50 Wh, representing 50% of full capacity. Alternatively or additionally, in the case of a constant voltage charger, the charge level may be determined with reference to a charging current. As the battery becomes increasingly charged with a constant voltage charger, the charging current decreases. Thus, the charging current is inversely related to the charge level of the battery.

At block 105, according to one set of exemplary embodiments, a first charging voltage and a first charge level for the battery for substantially fully charging the battery are determined. The first charging voltage is determined as a voltage level which is necessary to ensure that the battery will be charged to its full capacity. Pursuant to this example, the first charge level is determined to be 100% of full capacity. However, in some situations, such as with an aging battery, it may be desirable to set the first charge level to a value that is less than 100%. Thus, according to a set of alternate embodiments, the first charge level charges the battery to a level that is less than substantially fully charged, such as 50% of full capacity or 75% of full capacity, for example.

Regardless of whether the first charge level is 100% or a lesser percentage, the first charge level is computed from battery specification information such as a datasheet, or from one or more measurements of battery voltage, or by using various combinations of datasheet information and battery voltage measurements. The first charge level is typically represented using a first SoC value which is a function of measured battery voltage, nominal battery voltage, other measurements such as current or temperature, or any of various combinations thereof. The mathematical function relating SoC to battery voltage indicates that SoC is proportional to battery voltage. In practice, measuring the first SoC value may be simplified algorithmically by using measured battery voltage to calculate the first SoC valu. Thus, the first charge level may be controlled based upon one or more measurements of battery voltage.

In general, maintaining a battery at the first charge level, which may be as high as 100% of full capacity, is much more than what is needed for many embedded electronic devices, where the battery is continually connected to a power source provided by the embedded system. It may be desirable to maintain some level of energy storage in the battery if the power source of the embedded system fails or experiences a temporary outage. However, in the event of a failure or temporary outage, maintaining hours or days of energy storage in the battery may be unnecessary.

In many situations, it is risky to maintain an unnecessarily high charge level on a battery. In fact, failure of moderate-capacity battery systems can result in thermal incidents, exposure to high temperatures, fire, combustion, and release of hazardous chemicals. Use of batteries in an enclosed space presents both safety issues and potential reputational damage to a device operator. This problem is further exacerbated when the electronic device is embedded in an inaccessible or hard to reach area, such as in a cabinet, in a seat, in a wall, or in a bulkhead, and cannot be quickly removed. Moreover, presently evolving regulatory requirements define distinct rules for the level of protection required in electronic devices as a function of battery capacity. Greater battery capacity implies a greater threat to safety and an increased level of regulatory scrutiny.

The operational sequence of FIG. 1 progresses to block 107 where a second charging voltage and a second charge level are determined for the battery that substantially reduces or eliminates a safety hazard associated with the battery. The second charging voltage is less than the first charging voltage and the second charge level is less than the first charge level. For purposes of illustration, if the battery has a maximum capacity in the range of 20 Wh to 100 Wh, the second charge level may be limited to no more than 2 Wh. More generally, according to a set of further embodiments disclosed herein, the second charge level may be limited to be no greater than 25% or 30% of the full charge capacity of the battery.

As was previously described in connection with the first charge level, the second charge level may also be derived from datasheet relationships. For example, a second SoC value for the second charge level may be determined as a function of a battery voltage measurement. According to one set of illustrative embodiments, the second charge level is determined as a level which does not pose an unacceptably high thermal incident risk, either based upon manufacturer recommendations or empirical experiments.

In many practical situations, the second SoC value for the second charge level would be much less than the first SoC value of 100%, and typically 20% to 40% of the first SoC value for the first charge level. The mathematical function relating SoC to battery voltage indicates that SoC is proportional to battery voltage. In practice, measuring the first and second SoC values may be simplified algorithmically by using measured battery voltage to calculate the first and second SoC values. Thus, the first and second charge levels may be controlled based upon one or more measurements of battery voltage. As the battery ages, its total charge capacity diminishes, rendering the battery safer from the standpoint of capacity management. Thus, basing the charging of the battery on a reduced level defined by the second charge level would provide for a substantial margin of safety.

Next, at block 109, the applied charging voltage is limited so that the actual charge level of the battery does not exceed the second charge level. Alternatively or additionally, the applied charging current is limited so that the actual charge level of the battery does not exceed the second charge level. According to a first set of further embodiments, block 109 is performed by monitoring for overcurrent, or monitoring for overvoltage, or monitoring for both overcurrent and overvoltage. Optionally, the overcurrent or overvoltage monitoring may be performed in conjunction with fused protection. According to a second set of further embodiments, block 109 is performed using firmware control of the SoC. According to a third set of further embodiments, block 109 is performed by monitoring the SoC and controlling the application of the charging voltage or the charging current to turn off the charging voltage or the charging current automatically in response to the second charge level being reached or exceeded.

Combinations of the foregoing approaches may also be employed. For example, overcurrent or overvoltage monitoring may be performed in conjunction with providing firmware control of the SoC. Likewise, overcurrent or overvoltage monitoring may be performed in conjunction with turning off the charging voltage or the charging current in response to the second charge level being reached or exceeded. Such approaches may be utilized, for example, in connection with portable electronic devices such as tablets, smartphones, personal digital assistants (PDAs), laptop computers, global positioning system (GPS) devices, and other battery-powered devices.

Limiting the charging of the battery to the second charge level results in a battery with a relatively low amount of stored energy, such that battery safety hazards are drastically reduced or eliminated. This allows battery-equipped commercial, industrial, and consumer electronic devices to be used in safety-critical environments, and to be safely used in enclosed spaces. For example, managing SoC down to low levels provides protection against short circuits applied to the battery, such that a short circuit will not result in a thermal event. Likewise, managing SoC down to low levels provides compliance with new shipping regulations mandating low SoCs on any batteries that are to be shipped.

In operational settings comprising aircraft, there is generally ample excess battery capacity. Most of the time, the battery is connected to a power supply. Intermittent outage periods may last for relatively short bursts of approximately 100 milliseconds in duration. Accordingly, in these operational settings, there is no need to charge the battery to full (100%) capacity levels. Rather, one may charge the battery to a low level, such as 30% or less of full capacity, with no loss of functionality in the event of a typical power failure.

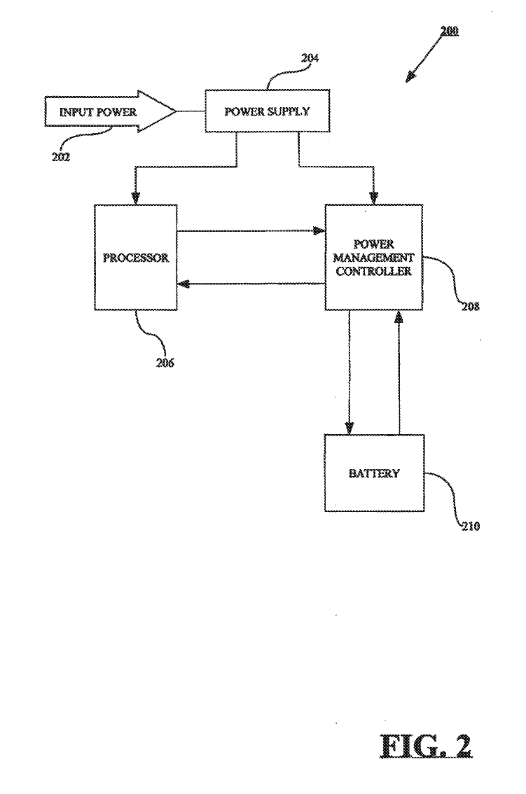

FIG. 2 illustrates an exemplary apparatus 200 on which the method of FIG. 1 may be performed in accordance with one or more embodiments of the present invention. This apparatus 200 may comprise a mobile computing device, such as a personal computer, a laptop, a tablet device, a mobile internet device, a personal digital assistant, or a smartphone that provides mobile operation and that includes a rechargeable battery power source. A source of input power 202 is applied to a power supply 204. The source of input power 202 may be external to the apparatus 200. For example, the input power 200 may be an AC mains line from the local electric utility, a vehicular power system, a generator, an alternator, or any other source of electric power. The power supply 204 converts the input power to a current level and a voltage level suitable for powering a processor 206 and a power management controller 208.

The processor 206 includes logic circuitry that responds to and processes a set of basic instructions that drive a computer. For purposes of illustration, the processor 206 may include an arithmetic logic unit (ALU), a floating point unit (FPU), registers, and a cache memory. The ALU carries out arithmetic and logic operations on sets of operands in instructions. The FPU, also known as a math coprocessor or numeric coprocessor, a specialized coprocessor that manipulates numbers. The registers hold instructions and other data. Registers supply operands to the ALU and store the results of operations. Cache memory may include an L1 cache and an L2 cache. The inclusion of the L1 and L2 caches saves time compared to the processor 206 having to fetch data from random access memory (RAM).

The processor 206 may, but need not, be implemented using a microprocessor. A microprocessor refers to a processor having its elements contained on a single integrated circuit (IC) chip. Likewise, the processor 206 may, but need not, be implemented using a multi-core processor. Multi-core processors contain two or more processors for enhanced performance, reduced power consumption and more efficient simultaneous processing of multiple tasks. Multi-core set-ups are similar to having multiple, separate processors installed in the same computer, but because the processors are physically plugged into a single socket, the connection between the processor cores is faster.

The processor 206 is operatively coupled to the power management controller 208. The power management controller 208 may be implemented using a specialized power management integrated circuit chip or component. The processor 206 receives sensor and monitor signals from the power management controller 208. The processor sends charge control commands to the power management controller 208. The power management controller 208 monitors and senses operations and conditions for a battery 210. These operations and conditions include two or more of a battery voltage, a battery current, a present battery charge level, a total battery capacity, a present sensed temperature, and, optionally, other factors. The power management controller 208 is configured for preventing overcharges, deep discharges, and over-current conditions of the battery 210, and is also configured for providing safe battery charging. Moreover, the processor 206 and the power management controller 208 are configured for implementing the procedure of FIG. 1.

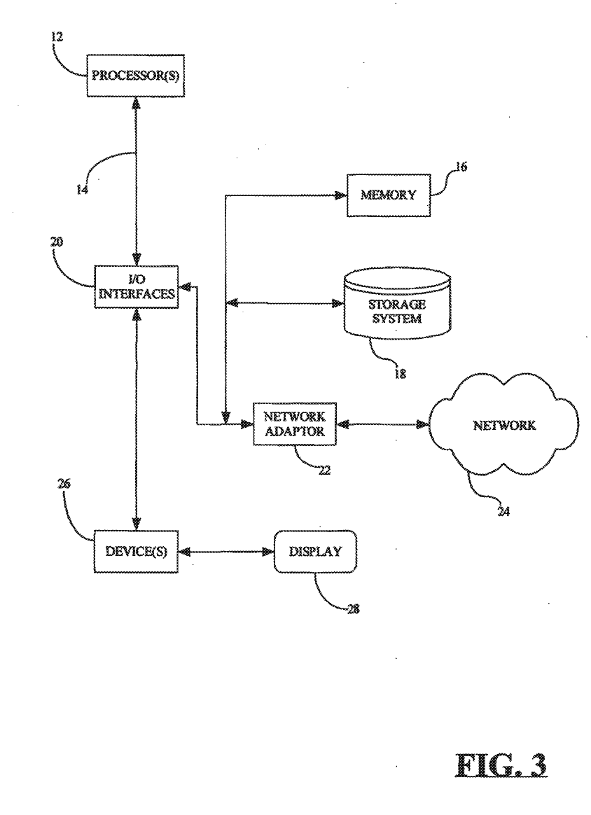

FIG. 3 illustrates a schematic of an exemplary computer or processing system that may implement any of the methods of FIG. 1, in one set of embodiments of the present disclosure. The computer system is only one example of a suitable processing system and is not intended to suggest any limitation as to the scope of use or functionality of embodiments of the methodology described herein. The processing system shown may be operational with numerous other general purpose or special purpose computing system environments or configurations. Examples of well-known computing systems, environments, and/or configurations that may be suitable for use with the processing system shown in FIG. 3 may include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

The computer system may be described in the general context of computer system executable instructions, such as program modules, being executed by a computer system. Generally, program modules may include routines, programs, objects, components, logic, data structures, and so on that perform particular tasks or implement particular abstract data types. The computer system may be practiced in distributed cloud computing environments where tasks are performed by remote processing devices that are linked through a communications network. In a distributed cloud computing environment, program modules may be located in both local and remote computer system storage media including memory storage devices.

The components of the computer system may include, but are not limited to, one or more processors or processing units 12, a system memory 16, and a bus 14 that couples various system components including system memory 16 to processor 12. The processor 12 may include a module that performs the methods described herein. The module may be programmed into the integrated circuits of the processor 12, or loaded from memory 16, storage device 18, or network 24 or combinations thereof.

Bus 14 may represent one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

The computer system may include a variety of computer system readable media. Such media may be any available media that is accessible by computer system, and it may include both volatile and non-volatile media, removable and non-removable media.

System memory 16 can include computer system readable media in the form of volatile memory, such as random access memory (RAM) and/or cache memory or others. The computer system may further include other removable/non-removable, volatile/non-volatile computer system storage media. By way of example only, storage system 18 can be provided for reading from and writing to a non-removable, non-volatile magnetic media (e.g., a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 14 by one or more data media interfaces.

The computer system may also communicate with one or more external devices 26 such as a keyboard, a pointing device, a display 28, etc.; one or more devices that enable a user to interact with computer system; and/or any devices (e.g., network card, modem, etc.) that enable computer system to communicate with one or more other computing devices. Such communication can occur via Input/Output (I/O) interfaces 20.

Still yet, the computer system can communicate with one or more networks 24 such as a local area network (LAN), a general wide area network (WAN), and/or a public network (e.g., the Internet) via network adapter 22. As depicted, network adapter 22 communicates with the other components of computer system via bus 14. It should be understood that although not shown, other hardware and/or software components could be used in conjunction with the computer system. Examples include, but are not limited to: microcode, device drivers, redundant processing units, external disk drive arrays, RAID systems, tape drives, and data archival storage systems, etc.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

While the present invention has been described in connection with the preferred embodiments of the various figures, it is to be understood that other similar embodiments may be used or modifications or additions may be made to the described embodiment for performing the same function of the present invention without deviating therefrom. Therefore, the present invention should not be limited to any single embodiment, but rather construed in breadth and scope in accordance with the recitation of the appended claims.

What is claimed is:

1. A computer-implemented method for performing intelligent safety management for a battery, the method comprising:
applying a charging voltage to the battery;
monitoring an actual charge level of the battery;
determining a first charging voltage and a first charge level for the battery for charging the battery;
determining a second charging voltage and a second charge level for the battery, wherein the second charging voltage is less than the first charging voltage and the second charge level is less than the first charge level; and
limiting the applied charging voltage so that the actual charge level of the battery does not exceed the second charge level.

2. The computer-implemented method of claim 1 wherein the limiting is performed by monitoring for overcurrent, or by monitoring for overvoltage, or monitoring for both overcurrent and overvoltage.

3. The computer-implemented method of claim 2 wherein the limiting is performed using firmware to limit the actual charge level of the battery to no greater than the second charge level.

4. The computer-implemented method of claim 2 wherein the limiting is performed by turning off the applied charging voltage in response to the actual charge level meeting or exceeding the second charge level.

5. The computer-implemented method of claim 1 further comprising determining the first charge level as 100% of a full charge capacity of the battery; and limiting the second charge level to be no greater than 30% of the full charge capacity of the battery.

6. A computer-implemented method for performing intelligent safety management for a battery, the method comprising:
applying a charging current to the battery;
monitoring an actual charge level of the battery;
determining a first charging current and a first charge level for the battery for charging the battery;
determining a second charging current and a second charge level for the battery, wherein the second charging current is less than the first charging current and the second charge level is less than the first charge level; and
limiting the applied charging current so that the actual charge level of the battery does not exceed the second charge level.

7. The computer-implemented method of claim 6 wherein the limiting is performed by monitoring for overcurrent, or by monitoring for overvoltage, or monitoring for both overcurrent and overvoltage.

8. The computer-implemented method of claim 7 wherein the limiting is performed using firmware to limit the actual charge level of the battery to no greater than the second charge level.

9. The computer-implemented method of claim 7 wherein the limiting is performed by turning off the applied charging current in response to the actual charge level meeting or exceeding the second charge level.

10. The computer-implemented method of claim 6 further comprising determining the first charge level as 100% of a full charge capacity of the battery; and limiting the second charge level to be no greater than 30% of the full charge capacity of the battery.

11. A computer program product comprising a computer-readable storage medium having a computer-readable program stored therein, wherein the computer-readable program, when executed on a computing device including at least one processor, causes the at least one processor to:
apply a charging voltage from a power supply to the battery;
monitor an actual charge level of the battery;
determine a first charging voltage and a first charge level for the battery for charging the battery;
determine a second charging voltage and a second charge level for the battery, wherein the second charging voltage is less than the first charging voltage and the second charge level is less than the first charge level; and
limit the applied charging voltage so that the actual charge level of the battery does not exceed the second charge level.

12. The computer program product of claim 11 further configured for performing the limiting by monitoring for overcurrent, or by monitoring for overvoltage, or monitoring for both overcurrent and overvoltage.

13. The computer program product of claim 12 further configured for performing the limiting using firmware to limit the actual charge level of the battery to no greater than the second charge level.

14. The computer program product of claim 12 further configured for performing the limiting by turning off the applied charging voltage in response to the actual charge level meeting or exceeding the second charge level.

15. The computer program product of claim 11 further configured for determining the first charge level as 100% of a full charge capacity of the battery; and limiting the second charge level to be no greater than 30% of the full charge capacity of the battery.

16. A computer program product comprising a computer-readable storage medium having a computer-readable program stored therein, wherein the computer-readable program, when executed on a computing device including at least one processor, causes the at least one processor to:
apply a charging current from a power supply to the battery;
monitor an actual charge level of the battery;
determine a first charging current and a first charge level for the battery for charging the battery;
determine a second charging current and a second charge level for the battery, wherein the second charging current is less than the first charging current and the second charge level is less than the first charge level; and
limit the applied charging current so that the actual charge level of the battery does not exceed the second charge level.

17. The computer program product of claim 16 further configured for performing the limiting by monitoring for overcurrent, or by monitoring for overvoltage, or monitoring for both overcurrent and overvoltage.

18. The computer program product of claim 17 further configured for performing the limiting using firmware to limit the actual charge level of the battery to no greater than the second charge level.

19. The computer program product of claim 17 further configured for performing the limiting by turning off the applied charging current in response to the actual charge level meeting or exceeding the second charge level.

20. The computer program product of claim 16 further configured for determining the first charge level as 100% of a full charge capacity of the battery; and limiting the second charge level to be no greater than 30% of the full charge capacity of the battery.

21. An apparatus comprising a processor and a memory coupled to the processor, wherein the memory comprises instructions which, when executed by the processor, cause the processor to:
apply a charging voltage from a power supply to the battery;
monitor an actual charge level of the battery;
determine a first charging voltage and a first charge level for the battery for charging the battery;
determine a second charging voltage and a second charge level for the battery, wherein the second charging voltage is less than the first charging voltage and the second charge level is less than the first charge level; and
limit the applied charging voltage so that the actual charge level of the battery does not exceed the second charge level.

22. The apparatus of claim 21 further configured for performing the limiting by monitoring for overcurrent, or by monitoring for overvoltage, or monitoring for both overcurrent and overvoltage.

23. The apparatus of claim 22 further configured for performing the limiting using firmware to limit the actual charge level of the battery to no greater than the second charge level.

24. The apparatus of claim 22 further configured for performing the limiting by turning off the applied charging voltage in response to the actual charge level meeting or exceeding the second charge level.

25. The apparatus of claim 21 further configured for determining the first charge level as 100% of a full charge capacity of the battery; and limiting the second charge level to be no greater than 30% of the full charge capacity of the battery.

26. An apparatus comprising a processor and a memory coupled to the processor, wherein the memory comprises instructions which, when executed by the processor, cause the processor to:
apply a charging current from a power supply to the battery;
monitor an actual charge level of the battery;
determine a first charging current and a first charge level for the battery for charging the battery;
determine a second charging current and a second charge level for the battery, wherein the second charging current is less than the first charging current and the second charge level is less than the first charge level; and
limit the applied charging current so that the actual charge level of the battery does not exceed the second charge level.

27. The apparatus of claim 26 further configured for performing the limiting by monitoring for overcurrent, or by monitoring for overvoltage, or monitoring for both overcurrent and overvoltage.

28. The apparatus of claim 27 further configured for performing the limiting using firmware to limit the actual charge level of the battery to no greater than the second charge level.

29. The apparatus of claim 27 further configured for performing the limiting by turning off the applied charging current in response to the actual charge level meeting or exceeding the second charge level.

30. The apparatus of claim 26 further configured for determining the first charge level as 100% of a full charge capacity of the battery; and limiting the second charge level to be no greater than 30% of the full charge capacity of the battery.
